(19) United States
(12) Patent Application Publication
(10) Pub. No.: US 2009/0302349 A1
(43) Pub. Date: Dec. 10, 2009

(54) STRAINED GERMANIUM FIELD EFFECT TRANSISTOR AND METHOD OF FABRICATING THE SAME

(75) Inventors: Min Hung Lee, Hsinchu (TW); Cheng Yeh Yu, Hsinchu (TW); Chee Wee Liu, Hsinchu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Industrial Technology Research Institute, Hsin-Chu (TW)

(21) Appl. No.: 12/540,216

(22) Filed: Aug. 12, 2009

Related U.S. Application Data
(63) Continuation-in-part of application No. 11/216,179, filed on Sep. 1, 2005.

(30) Foreign Application Priority Data
Jun. 15, 2005 (TW) 94119896

(51) Int. Cl. H01L 29/78; H01L 21/20

(52) U.S. Cl. 257/192; 438/507; 257/E29.255; 257/E21.09

(57) ABSTRACT

A strained germanium field effect transistor (FET) and method of fabricating the same is related to the strained Ge field effect transistor with a thin and pure Ge layer as a carrier channel. The pure Ge layer with the thickness between 1 nm and 10 nm is formed between an unstrained substrate and a gate insulation layer, and directly contacts with the unstrained substrate. The gate is disposed on the gate insulation layer. The germanium layer is used as a carrier transport channel of the strained Ge FET to improve the drive current and the carrier mobility, and to increase the devices performance effectively. Furthermore, a Si protective layer with extremely thin thickness can be deposed between and directly contacts with the gate insulation layer and the pure Ge layer.

### CROSS-REFERENCE TO RELATED APPLICATIONS

This application is a continuation-in-part patent application of U.S. application Ser. No. 11/216,179 filed on Sep. 1, 2005, the entire contents of which are hereby incorporated by reference for which priority is claimed under 35 U.S.C. § 120.

### BACKGROUND

1. Technical Field

The disclosure relates to a field effect transistor (FET). More particularly, the disclosure relates to a strained germanium FET and method of fabricating the same.

2. Background Art

For a long time, Germanium (Ge) is considered to have better carrier mobility than Si, and the strained Ge also exhibits more excellent transport property than Si or strained Si, therefore, the application of the Ge process is considered to be one of the candidate of developing the high performance property of the Complementary Metal Oxide Semiconductor (CMOS) in the future. However, nowadays, the Ge process technique is difficult to fabricate a strained Ge with high quality. The earth content of Ge is far rarer than Si. The process cost is very high. And it has not been found that the Ge has the similar interface as that between Si and SiO₂. These are all the difficulties in substituting the Si with the Ge in the transistor processes well as the main process of the CMOS.

The Ge channel transistor structure according to the prior art (U.S. Pat. No. 6,723,622) is the epitaxial pure Ge growing on a relaxed SiGe layer. In order to reduce the defects caused by the lattice mismatch of the relaxed SiGe layer and the Si substrate, a thick SiGe graded buffer layer (about 1 μm) is grown between the Si substrate and the relaxed SiGe layer. However, the recent growing method of it is difficult to obtain the higher Ge concentration and the relaxed SiGe buffer with high quality. This may lead threading dislocation defects to the relaxed SiGe buffer layer. Due to lattice constant mismatch results a crosshatch on the SiGe surface, such that the surface is rough and the transistor quality is degraded.

Another prior art (U.S. Pat. No. 6,287,903) is to cover the Si crystal substrate with an epitaxial ultrathin Ge layer as a protective layer to add an interfacial layer between the Si crystal substrate and a high-K dielectric layer, the carrier channel of which is still the Si crystal material.

### SUMMARY

The embodiment provides a strained Ge FET and method of fabricating the same, thereby to solve the problems existed in the prior arts.

A strained Ge FET disclosed in the embodiment comprises an unstrained substrate, a pure Ge layer, a gate insulation layer and a gate.

The pure Ge layer is disposed on and directly contacts with the unstrained substrate, and the thickness of the pure Ge layer is between 1 nm and 10 nm. The thickness of the pure Ge layer can be 4 nm.

The gate insulation layer is disposed on the pure Ge layer. The gate is disposed on the gate insulation layer.

In the strained Ge FET, the pure Ge layer 12 is single strained, and the other layer is unstrained. Therefore, the pure Ge layer 12 is single channel of the strained Ge FET.

After the pure Ge layer is formed, an unstrained Si protective layer is formed on the pure Ge layer and fully covers the upper surface of the pure Ge layer. Then, the Si protective layer is removed before forming the gate insulation layer.

The Ge layer, the Si protective layer and the Si buffer layer can be formed by using the UHVCVD under a temperature of 525° C.

Further scope of applicability of the embodiment will become apparent from the detailed description given hereinafter. However, it should be understood that the detailed description and specific examples, while indicating embodiments, are given by way of illustration only, since various changes and modifications within the spirit and scope of the invention will become apparent to those skilled in the art from this detailed description.

### BRIEF DESCRIPTION OF THE DRAWINGS

The embodiment will become more fully understood from the detailed description given herein below for illustration only for, and thus are not limitative of the embodiment, and wherein:

FIG. 1 is a schematic view of an embodiment of a FET substrate in a strained Ge FET;

FIG. 2A is a schematic view of the strained Ge FET according to first embodiment;

FIG. 2B is a schematic view of the strained Ge FET according to second embodiment;

FIG. 3 is a schematic view of another embodiment of a FET substrate in a strained Ge FET;

FIG. 4A is a schematic view of the strained Ge FET according to third embodiment;

FIG. 4B is a schematic view of the strained Ge FET according to fourth embodiment;

FIG. 5 is a simulation view of an inversion layer thickness of a transistor operated under the inversion region, which is calculated by the simulation software;

FIG. 6 is a Raman shift spectrum for the bulk Ge FET and strained Ge FET;

FIG. 7 is a plot of the interface trap density of bulk Si FET and strained Ge FET (the strained Ge FETs have different thicknesses of the Si protective layers before the Si protective layers are removed.);

FIG. 8 is a graph of the drain current output characteristics of bulk Si FET and strained Ge FET; and

FIG. 9 is a comparison of hole mobility for bulk Si FET and strained Ge FET.

### DETAILED DESCRIPTION

The embodiments will be described in details in order to further illustrate the objects, constructions, features and functions. The descriptions about the summary mentioned above and the detailed description below are used to illustrate and explain the principles of the embodiment, and to provide a further explanation of the embodiment.

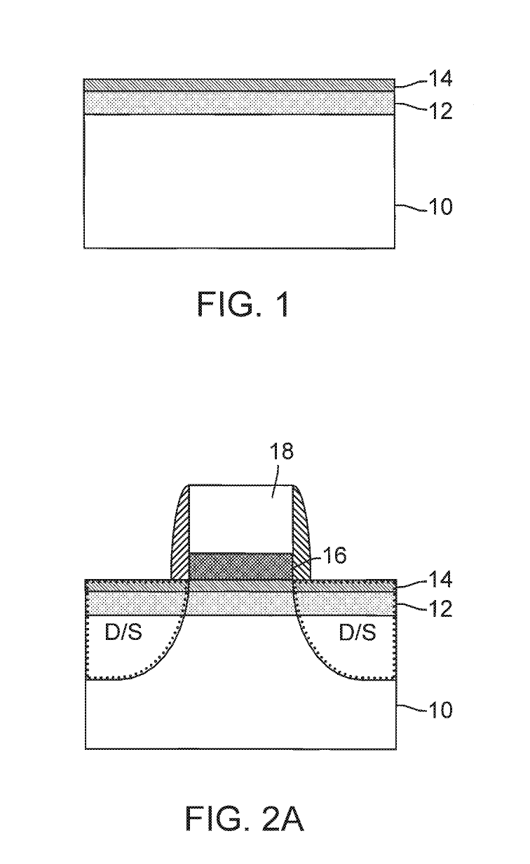

Referring to FIG. 1, it is a schematic view of a FET substrate. A pure Ge layer 12 is grown directly on a Si substrate 10 by compressively strain the epitaxy at 525° C. using the Ultra High Vacuum Chemical Vapor Deposition (UHVCVD) with extremely low growth rate. The growth rate can be between 0.1 nm per min and 3 nm per min. The growth rate for growth at 525° C. can be 0.9 nm per min.

Since the pure Ge layer 12 is directly formed on the unstrained Si substrate 10, there is no question about alloy scattering and there is the largest variation of lattice constant between them. In other word, the pure Ge layer 12 is formed on the unstrained Si substrate 10 without any stress-buffer layer between them, so there is the largest variation of lattice constant between them, such that the Ge layer has the largest compressively strain due to the variation of lattice constant, larger than SiGe layer. Therefore, the performance of the element (i.e. strained Ge FET) is much promoted by using the Ge layer as a transistor carrier channel.

Under epitaxy technique, if the pure Ge layer 12 is too thick, Ge atoms easily aggregate to island during growing the pure Ge layer 12; if the pure Ge layer 12 is too thin, it is difficult to growing the uniform pure Ge layer and the carriers do not completely pass through the pure Ge layer 12 with high mobility. To growing the uniform pure Ge layer 12 as the transistor carrier channel and fully covering the upper surface of the Si substrate 10 with the pure Ge layer 12, the thickness of the pure Ge layer 12 need to be controlled, the thickness is ranging from 1 nm to 10 nm. The thickness of the pure Ge layer 12 can be 4 nm.

The orientation of the Si substrate 10 can be shown as (100), (110) or (111), and the Si substrate 10 can be Si crystal substrate, bulk Si substrate or Si on insulator (SOI) substrate.

Furthermore, the thickness of the pure Ge layer 12 is changed or exhausted due to the pure Ge oxidizes, so a Si protective layer 14 is immediately formed on the pure Ge layer 12 and fully covers the upper surface of the pure Ge layer 12 after the pure Ge layer 12 is formed. Therefore, the Si protective layer 14 is unstrained and is used to protect the pure Ge layer 12 from oxidization, such that the pure Ge layer 12 holds the thickness thereof. In an embodiment, the Si protective layer 14 is formed on the pure Ge layer 12 the epitaxial Si growth at 525° C. using the UHVCVD with extremely low growth rate. The growth rate can be between 0.1 nm per min and 3 nm per min. The growth rate for growth at 525° C. can be 0.9 nm per min.

The Si protective layer 14 can be made of pure Si. However, the Si protective layer 14 can oxidize to form native oxide due to exposed to the air. Therefore, the material of the Si protective layer 14 can be pure Si or a combination of pure Si and silicon oxide.

The Si protective layer 14 is first removed by HF dip before forming a gate insulation layer 16.

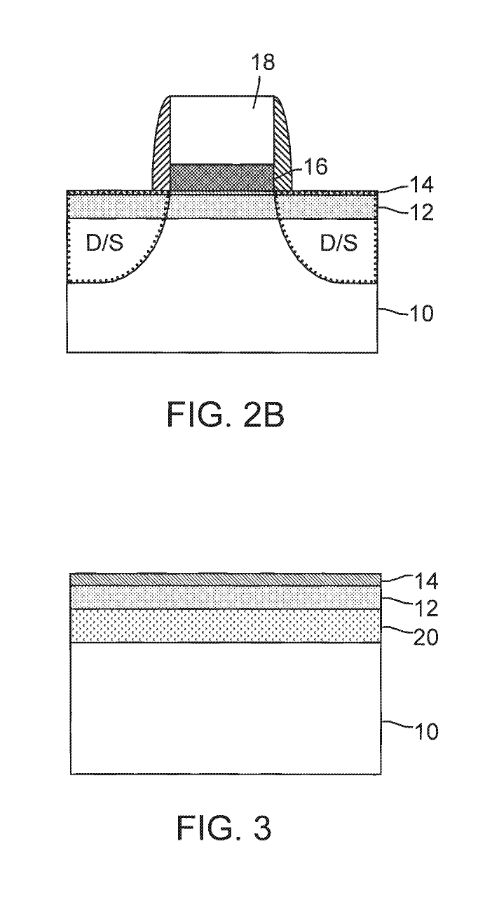

When the thickness of the Si protective layer 14 is appropriately designed, the thickness of the Si protective layer 14 can be 3 nm, the Si protective layer 14 can be completely formed into the native oxide and the native oxide can be completely removed. Therefore, the pure Ge layer 12 is a surface channel, so as to aid lower short channel effect under scaling down the element. Then, the gate insulation layer 16 is directly formed on the pure Ge layer 12, as shown in FIG. 2A.

Besides, the Si protective layer 14 can incompletely removed, so as to remain the Si protective layer 14 with extremely thin thickness as an interface between the gate insulation layer 16 and the pure Ge layer 12, to obtain a better interface equivalent to the conventional Si process transistor. The thickness of the remained Si protective layer 14 can be between 0.5 nm to 20 nm. The thickness of the remained Si protective layer 14 can be 1 nm. Therefore, the gate insulation layer 16 is directly formed on the Si protective layer 14, as shown in FIG. 2B. Furthermore, after the Si protective layer 14 is removed, the gate insulation layer 16 can be immediately formed on the remained Si protective layer 14, to avoid the remained Si protective layer 14 oxidizing into the native oxide.

Finally, a gate 18 is formed on the gate insulation layer 16, and source/drain D/S (the region surrounded by the dotted line is shown in FIGS. 2A and 2B) is formed in the strained Ge FET substrate and beside two sides of the gate 18, as shown in FIGS. 2A and 2B, to form the strained Ge FET. In the strained Ge FET, the pure Ge layer 12 is singlestrained, and the other layer is unstrained. Therefore, the pure Ge layer 12 is singlechannel of the strained Ge FET.

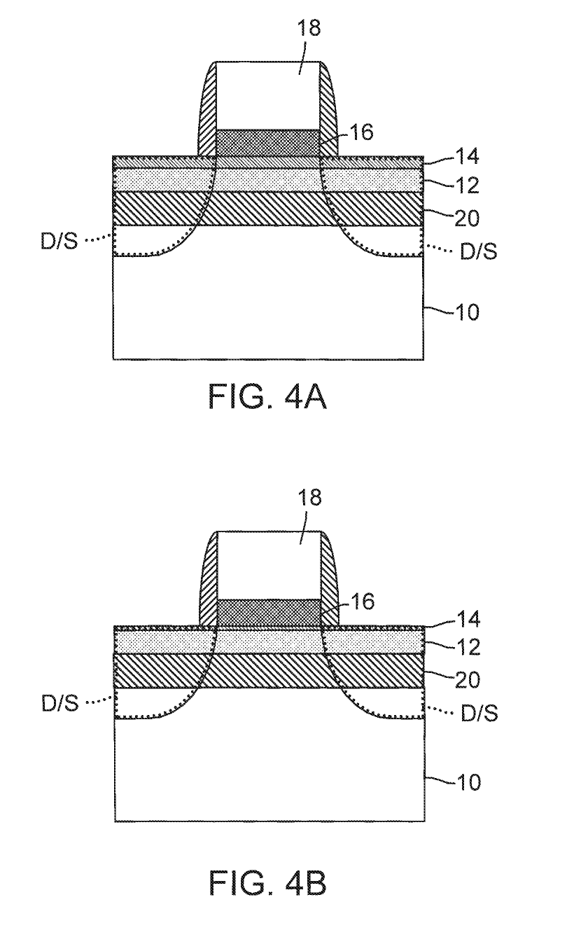

Furthermore, since the Si substrate 10 is exposed to air, the surface of the Si substrate 10 may be have dust and/or impurity and/or oxidize. For ensuring the quality of epitaxy, the Si buffer layer 20 is formed on the Si substrate 10, as shown in FIG. 3, and then other layer is formed thereon, as shown in FIGS. 4A and 4B. The Si buffer layer 20 also is unstrained. Herein, the Si buffer layer 20 can be formed on the Si substrate 10 by the epitaxial Si growth at 525° C. using the UHVCVD with extremely low growth rate, for assisting the growth of the Ge layer 12. The thickness of the Si buffer layer 20 can be between 0 μm and 1000 μm. The thickness of the Si buffer layer 20 can be about 40 nm. The growth rate can be between 0.1 nm per min and 3 nm per min. The growth rate for growth at 525° C. can be 0.9 nm per min.

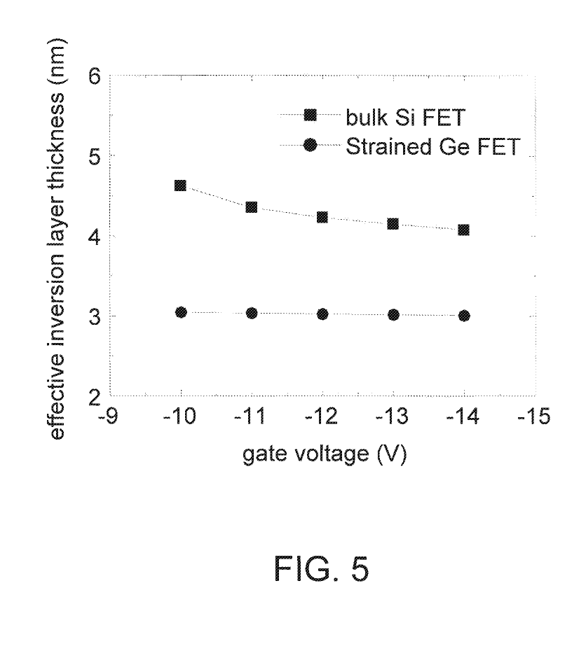

FIG. 5 is a simulation view of an inversion layer thickness of a transistor operated under the inversion region, which is calculated by the simulation software. It can be seen from the simulation view that the inversion layer thickness of the strained Ge FET is thinner than that of the Si FET, due to the quantum confinement effect, and the inversion layer thickness of the strained Ge FET is about 3 nm. In order to enable the carriers transport in the pure Ge layer 12 to utilize the excellent transport characteristics of the strained Ge, the pure Ge layer 12 of the embodiment should thicker than 3 nm.

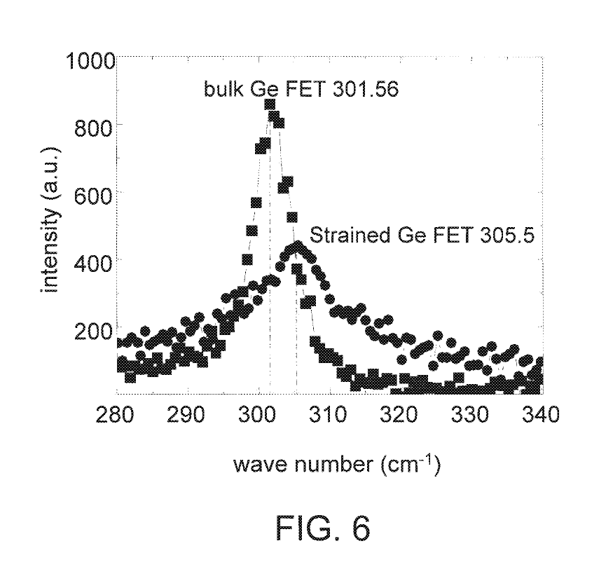

FIG. 6 is a Raman shift spectrum for the bulk Ge substrate and strained Ge layer. According to the Raman shift data of the strained Ge layer compared with the bulk Ge substrate, it can confirm that the pure Ge layer 12 of the strained Ge substrate is indeed under compressively strain.

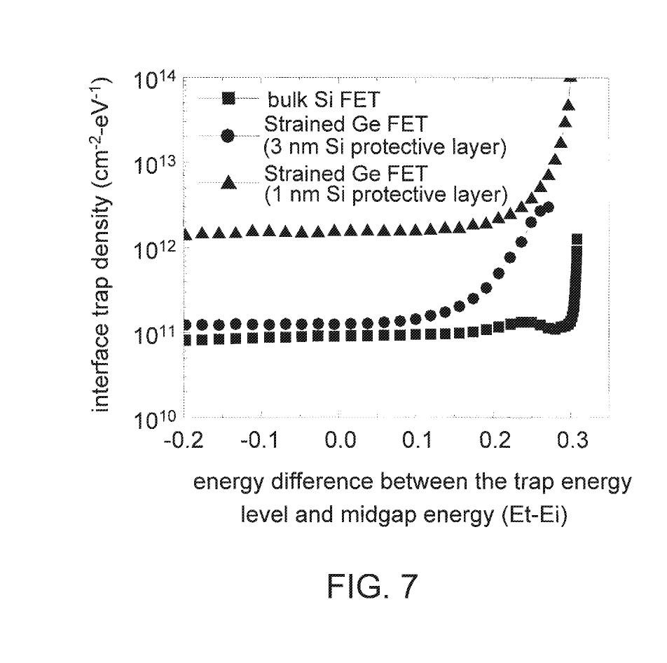

FIG. 7 is a plot of the interface trap density of bulk Si FET and strained Ge FET. It can be observed from the comparison of the interface trap density, since the Si protective layer 14 is on the pure Ge layer 12, if the deposited Si protective layer 14 (before being removed) is thicker than 3 nm, the interface trap density on the surface of the strained Ge FET is similar to that of the bulk Si FET, and therefore the disadvantages of the Ge channel transistor high interface trap density with 1 nm Si protective layer (before being removed) are prevent effectively. In other words, the deposited Si protective layer 14 with the thickness of thicker than 3 nm has the better capability to protect the pure Ge layer 12 from oxidization.

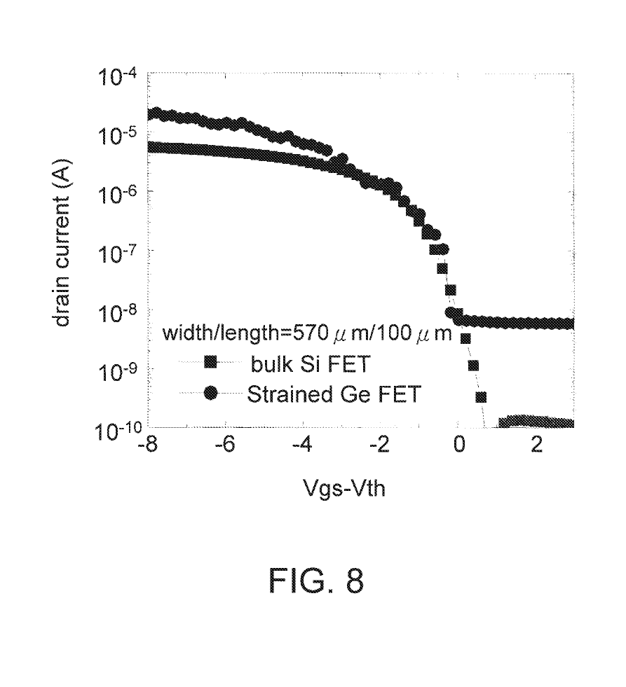

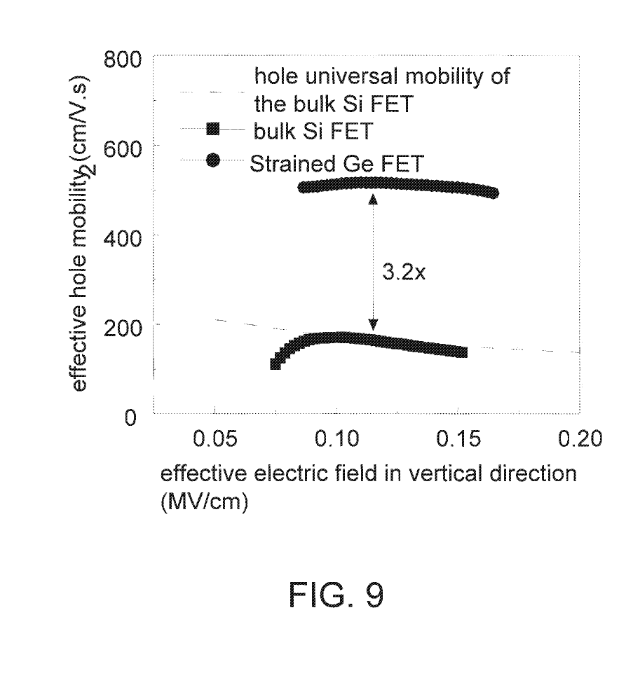

FIG. 8 is a graph of the drain current output characteristics of bulk Si FET and strained Ge FET. It can be observed that the strained Ge FET can improve the drain output current effectively. FIG. 9 is a comparison of hole mobility for bulk Si FET and strained Ge FET. It can be observed from that the strained Ge FET can improve the hole mobility by approximately 3.2 times effectively.

In a strained Ge FET and method of fabricating the same according to the embodiment, a thin and pure Ge layer is used as a carrier channel of a strained Ge FET, to improve the drive current and the carrier mobility.

The embodiment being thus described, it will be obvious that the same may be varied in many ways. Such variations are not to be regarded as a departure from the spirit and scope of the embodiment, and all such modifications as would be obvious to one skilled in the art are intended to be included within the scope of the following claims.

What is claimed is:

1. A strained Ge FET, comprising:
an unstrained substrate;
a pure Ge layer disposed on and directly contacting with the unstrained substrate, wherein the thickness of the pure Ge layer is between 1 nm and 10 nm;
a gate insulation layer disposed on the pure Ge layer; and
a gate disposed on the gate insulation layer.

2. The strained Ge FET of claim 1, wherein the thickness of the pure Ge layer is 4 nm.

3. The strained Ge FET of claim 1, wherein the pure Ge layer directly contacts with the gate insulation layer to be a surface channel of the strained Ge FET.

4. The strained Ge FET of claim 1, wherein the pure Ge layer is singlechannel of the strained Ge FET.

5. The strained Ge FET of claim 1, further comprising:
a Si protective layer disposed between and directly contacting with the pure Ge layer and the gate insulation layer, wherein the Si protective layer is unstrained and the thickness of the Si protective layer is between 0.5 nm and 20 nm.

6. The strained Ge FET of claim 1, wherein the thickness of the Si protective layer is 1 nm.

7. The strained Ge FET of claim 1, further comprising:
a Si protective layer disposed between and directly contacting with the pure Ge layer and the gate insulation layer, wherein the Si protective layer is unstrained and the thickness of the Si protective layer is between 0.5 nm and 20 nm.

8. The strained Ge FET of claim 1, wherein the thickness of the Si protective layer is 1 nm.

9. The strained Ge FET of claim 1, wherein the unstrained substrate is a Si substrate.

10. The strained Ge FET of claim 1, wherein the unstrained substrate comprising:
a Si substrate; and
a Si buffer layer disposed between the Si substrate and the pure Ge layer and directly contacting with the pure Ge layer.

11. The strained Ge FET of claim 1, wherein the gate insulation layer is a SiO₂ material or a high-K dielectric layer material.

12. A fabricating method of a strained Ge FET, comprising:
providing an unstrained substrate;
forming a pure Ge layer directly contacting with the unstrained substrate on the unstrained substrate by compressively strain epitaxy at 525° C. using a Ultra High Vacuum Chemical Vapor Deposition (UHVCVD), with the thickness between 1 nm to 10 nm;
forming a Si protective layer directly contacting with the pure Ge layer on the pure Ge layer at 525° C. by the UHVCVD, wherein the Si film protective layer is an unstrained layer;
removing the Si protective layer;
forming a gate insulation layer directly contacting with one of the pure Ge layer and the Si protective layer; and
forming a gate on the gate insulation layer.

13. The fabrication method of the strained Ge FET of claim 12, wherein the step of forming a pure Ge layer comprising:
forming the pure Ge layer at 525° C. by the UHVCVD, with thickness of 4 nm.

14. The fabrication method of the strained Ge FET of claim 12, wherein the step of forming a Si protective layer comprising:
forming the Si protective layer at 525° C. by the UHVCVD, with thickness of 3 nm.

15. The fabrication method of the strained Ge FET of claim 12, wherein the step of removing the Si protective layer comprising:
completely removing the Si protective layer before forming the gate insulation layer;
wherein the formed gate insulation layer directly contacts with the pure Ge layer.

16. The fabrication method of the strained Ge FET of claim 12, wherein the step of removing the Si protective layer comprising:
partly removing the Si protective layer before forming the gate insulation layer, to remain the Si protective layer with the thickness of 1 nm;
wherein the gate insulation layer directly contacts with the Si protective layer.

17. The fabrication method of the strained Ge FET of claim 12, wherein the step of providing an unstrained substrate comprising:
providing a Si substrate; and
forming a Si buffer layer on the Si substrate before forming the pure Ge layer.

18. The fabrication method of the strained Ge FET of claim 12, wherein the UHVCVD works with a growth rate between 0.1 nm/min and 3 nm/min.

19. The fabrication method of the strained Ge FET of claim 18, wherein the UHVCVD works with the growth rate of 0.9 nm/min.
